(19) United States
(12) Patent Application Publication
(10) Pub. No.: US 2016/0182012 A1
(43) Pub. Date: Jun. 23, 2016

(54) TUNING FORK VIBRATOR

(71) Applicant: Samsung Electro-Mechanics Co., Ltd., Suwon-si (KR)

(72) Inventors: Seung Mo LIM, Suwon-si (KR); Dong Woo LEE, Suwon-si (KR); Won HAN, Suwon-si (KR); Ran Hee SHIN, Suwon-si (KR)

(73) Assignee: Samsung Electro-Mechanics Co., Ltd., Suwon-si (KR)

(21) Appl. No.: 14/918,273

(22) Filed: Oct. 20, 2015

(30) Foreign Application Priority Data
Dec. 23, 2014 (KR) 10-2014-0187104

(51) Int. Cl. H03H 9/21; H03H 3/02

(52) U.S. Cl. CPC H03H 9/21; H03H 3/02; H03H 2003/026

(57) ABSTRACT

A tuning fork vibrator includes: a vibration arm including one or more grooves extending depthwise in a first direction; and exciting electrodes configured to provide a level of driving force required for vibrations of the vibration arm, wherein the one or more grooves have a cross-sectional shape in which a depth of the one or more grooves decreases from a first point toward a second point, and the depth of the one or more grooves at the second point is 30% or more of the depth of the groove at the first point.

### CROSS-REFERENCE TO RELATED APPLICATION(S)

This application claims the benefit of Korean Patent Application No. 10-2014-0187104 filed on Dec. 23, 2014, in the Korean Intellectual Property Office, the entire disclosure of which is incorporated herein by reference for all purposes.

### BACKGROUND

1. Field

The following description relates to a tuning fork vibrator capable of having equivalent series resistance (ESR) characteristics.

2. Description of Related Art

A tuning fork vibrator is an example of one type of vibrator. The tuning fork vibrator includes one or more grooves formed in an arm in which vibrations are generated.

In order to increase efficiency of the tuning fork vibrator, a distance between electrodes needs to be significantly reduced. Therefore, the grooves need to be formed at a deep depth in the arm.

However, in a case in which the grooves are formed at an excessively deep depth, there is a problem in which grooves formed in different surfaces connect to each other. In addition, in a case in which a depth of a groove is deep, there is a problem in which equivalent series resistance (ESR) characteristics of the vibrator are deteriorated.

Therefore, the development of a tuning fork vibrator capable of improving both of vibration efficiency and ESR characteristics is desirable.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect, a tuning fork vibrator includes: a vibration arm including one or more grooves extending depthwise in a first direction; and exciting electrodes configured to provide a level of driving force required for vibrations of the vibration arm, wherein the one or more grooves have a cross-sectional shape in which a depth of the one or more grooves decreases from a first point toward a second point, and the depth of the one or more grooves at the second point is 30% or more of the depth of the one or more grooves at the first point.

The depth of the one or more grooves at the first point may be 30% or more of a height of the vibration arm in the first direction.

The one or more grooves may have a cross-sectional shape including lines having an angle of inclination with respect to a vertical line in the first direction.

The one or more grooves may be formed, respectively, in first and second surfaces of the vibration arm that are perpendicular to the first direction.

The one or more grooves may be formed in first and second surfaces of the vibration arm that are perpendicular to the first direction to be symmetrical to each other.

The one or more grooves may be formed lengthwise in a second direction, which is a length direction of the vibration arm.

The one or more grooves may be formed at predetermined gaps in a third direction, which is a width direction of the vibration arm.

The cross-sectional shape of the one or more grooves may satisfy the following Conditional Expression: 0.3<Dmin/Dmax<0.45, wherein Dmax is the depth of the one or more grooves at the first point and Dmin is the depth of the one or more grooves at the second point.

The cross-sectional shape of the one or more grooves may satisfy the following Conditional Expression: Dmin/W<2.0, wherein Dmin is the depth of the one or more grooves at the second point and W is a maximum width of the one or more grooves.

The cross-sectional shape of the one or more grooves may satisfy the following Conditional Expression: 0.16<Dmin/h<0.36, wherein Dmin is the depth of the one or more grooves at the second point.

The vibration arm may be formed of crystal.

The tuning fork vibrator may include a mass member formed on the vibration arm.

According to another general aspect, a tuning fork vibrator may include: a vibration arm including one or more grooves extending depthwise in a first direction; and mask patterns formed on the vibration arm at predetermined gaps between the mask patterns to form the one or more grooves, wherein a minimum depth of the one or more grooves is greater than a gap between the mask patterns.

The minimum depth (Dmin) of the one or more grooves may satisfy the following Conditional Expression with respect to the gap (G) between the mask patterns: 3.0<Dmin/G.

A maximum depth (Dmax) of the one or more grooves may satisfy the following Conditional Expression with respect to the gap (G) between the mask patterns: 4.0<Dmax/G.

The vibration arm may be formed of a material having mechanical directionality.

According to another general aspect, a method of manufacturing a tuning fork vibrator includes: forming mask patterns on at least one of an upper surface and a lower surface of a member forming a vibration arm; and etching the member to form a groove extending between the mask patterns along a length of the member, wherein the groove has a width in a direction corresponding to a direction of a gap between the mask patterns on the upper surface of the member or the lower surface of the member, and wherein the gap between the mask patterns is narrower than the width of the groove.

The groove may have a cross-sectional shape in which the depth of the groove decreases from a first point toward a second point, wherein the depth of the groove is perpendicular to the width of the groove.

Other features and aspects will be apparent from the following detailed description, the drawings, and the claims.

### BRIEF DESCRIPTION OF THE DRAWINGS

FIG. 1 is a plan view illustrating an example of a tuning fork vibrator.

FIG. 2 is a cross-sectional view of the tuning fork vibrator taken along line A-A′ of FIG. 1, according to an example.

FIG. 3 is a cross-sectional view of the tuning fork vibrator taken along line B-B′ of FIG. 1.

FIG. 4 is an enlarged view of part C illustrated in FIG. 3.

FIG. 5 is a graph illustrating a relationship between a minimum depth Dmin of a groove and equivalent series resistance (ESR).

FIG. 6 is a graph illustrating a relationship between a ratio (Dmin/Dmax) of a minimum depth of a groove to a maximum depth of the groove and ESR.

FIG. 7 is a view illustrating a process of forming grooves in the tuning fork vibrator.

FIG. 8 is an enlarged view of part D of FIG. 7 illustrating a change in a size of the groove depending on an etching time.

FIG. 9 is a cross-sectional view of another form of the tuning fork vibrator taken along line B-B′ of FIG. 1, according to an example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

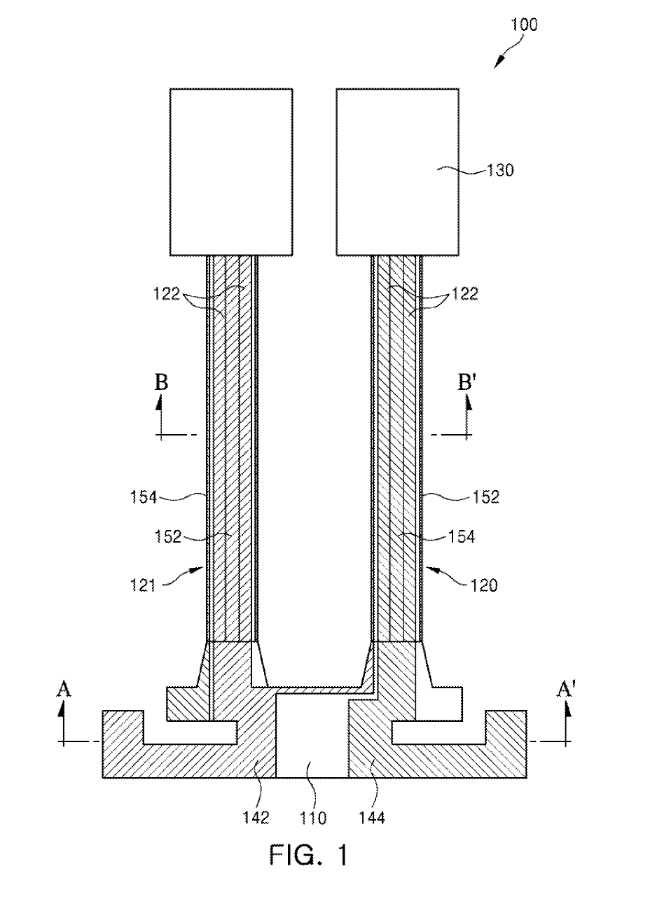

A tuning fork vibrator 100, according to an example, will be described with reference to FIG. 1.

The tuning fork vibrator 100, includes a support body 110 and a vibration arm 120. For example, the support body 110 may be configured to not be vibrated, and vibration arms 120 and 121 may be configured to be vibrated with respect to the support body 110. In addition, the tuning fork vibrator 100 includes mass members 130 configured to adjust a vibration frequency of the vibration arm 120.

The support body 110 is configured to be fixed to a substrate (not shown) or another member. For example, the support body 110 may be firmly fixed to the substrate by an adhesive or another means.

Connection electrodes 142 and 144 are formed in the support body 110. For example, the first connection electrode 142 may be formed on a portion of the support body 110, and the second connection electrode 144 may be formed on another portion of the support body 110.

The connection electrodes 142 and 144 are connected to exciting electrodes 152 and 154. For example, the first connection electrode 142 may be connected to the first exciting electrode 152, and the second connection electrode 144 may be connected to the second exciting electrode 154.

The vibration arms 120 and 121 may be configured to be vibrated by a level of driving force. For example, each of the vibration arms 120 and 121 may be configured so that one end (hereinafter referred to as a “fixed end”) thereof is fixed to the support body 110 and the other end (hereinafter referred to as a “free end”) thereof may freely move. For example, a pair of vibration arms 120 and 121 may extend lengthwise from one side of the support body 110 in a length direction of the tuning fork vibrator 100 (vertically in FIG. 1). The vibration arms 120 and 121 configured as described generate a predetermined frequency while the other ends thereof are vibrated in the one direction by an electrical signal.

One or more grooves 122 are formed in the vibration arms 120 and 121. For example, the one or more grooves 122 may be formed in at least one of first and second surfaces of the vibration arms 120 and 121. The configuration of the grooves 122 described facilitates vibrations of the vibration arms 120 and 121. In addition, the configuration of the grooves 122 described facilitates formation of the exciting electrode.

The vibration arms 120 and 121 may be formed of a material having a piezoelectric property. For example, the vibration arms 120 and 121 may be formed of crystal. As another example, the vibration arms 120 and 121 may be formed of a material having mechanical directionality.

The exciting electrodes 152 and 154 are formed on the vibration arms 120 and 121. For example, the first exciting electrodes 152 may be formed on portions of the vibration arms 120 and 121, and the second exciting electrodes 154 may be formed on other portions of the vibration arms 120 and 121.

The first and second exciting electrodes 152 and 154 substantially face each other. For example, the first exciting electrodes 152 may be formed on both side surfaces of the vibration arm 120, and the second exciting electrode 154 may be formed on the groove 122.

Positions of the first and second exciting electrodes 152 and 154 may be different from each other depending on the vibration arm 120. For example, forms of the exciting electrodes 152 and 154 formed on the first and second vibration arms 120 and 121 may be opposite to each other. For example, the first exciting electrodes 152 may be formed on both side surfaces of a first vibration arm 120, and the second exciting electrodes 154 may be formed on the groove 122 of the first vibration arm 120. As another example, the second exciting electrodes 154 may be formed on both side surfaces of the second vibration arm 121, and the first exciting electrode 152 may be formed on the groove 122 of the first vibration arm 120. The exciting electrodes 152 and 154 having the form as described above may be easily connected to the connection electrodes 142 and 144.

The mass members 130 are formed on the vibration arms 120 and 121. For example, the mass members 130 may be formed at the free ends of the vibration arms 120 and 121. The mass members 130 may have a predetermined mass. For example, masses of the mass members 130 may be greater than those of the vibration arms 120 and 121. However, a relationship between masses of the mass members 130 and the vibration arms 120 and 121 is not limited to the foregoing example. As another example, masses of the mass members 130 may be the same as or lesser than those of the vibration arms 120 and 121.

The mass member 130 may have a form in which an inner portion thereof is empty. For example, the mass member 130 may be manufactured in a hollow form. The mass member 130 may be formed of a material different from that of the vibration arms 120 and 121. For example, the mass member 130 may be formed of a metal, a resin, or the like.

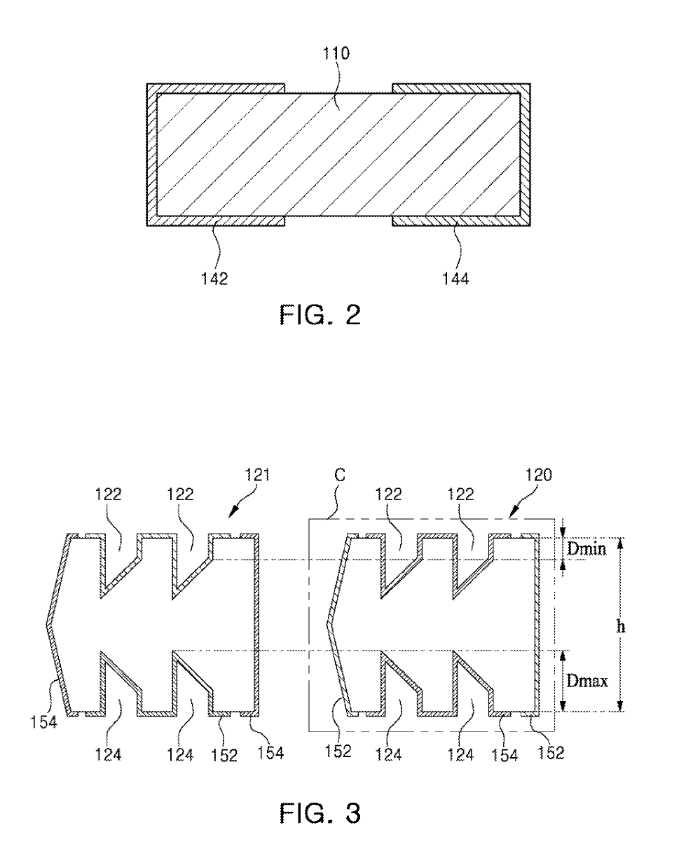

An example structure of a cross section of the tuning fork vibrator 100 taken along line A-A′ will be described with reference to FIG. 2.

As shown in FIG. 2, the support body 110 of the tuning fork vibrator 100 may be manufactured to be easily bonded to a substrate or a fixing body. For example, the support body 110 may have a rectangular cross-sectional shape. Since the support body 110 having this shape has a cross section of which a height is low and a width is wide, the support body 110 may be firmly fixed to the substrate or the fixing body. In addition, the support body 110 having this shape may be advantageous in making the tuning fork vibrator 100 thin.

An example structure of a cross section of the tuning fork vibrator 100 taken along line B-B′ will be described with reference to FIG. 3.

As shown in FIG. 3, two grooves 122 are formed in each of first surfaces (upper surfaces in FIG. 3) of the vibration arms 120 and 121, and two grooves 124 are formed in each of second surfaces (lower surfaces in FIG. 3) of the vibration arms 120 and 121. The grooves 122 and 124 may be formed depthwise in a first direction (a vertical direction in FIG. 3).

The first and second grooves 122 and 124 may have substantially the same shape. For example, the first and second grooves 122 and 124 may be symmetrical to each other in relation to a horizontal line bisecting the vibration arms 120 and 121 in FIG. 3.

A depth of each of the grooves 122 and 124 may have a predetermined ratio with respect to a height h of each of the vibration arms 120 and 121. For example, a maximum depth Dmax of each of the grooves 122 and 124 may satisfy the following Conditional Expression with respect to the height h of each of the vibration arms 120 and 121:

0.4<Dmax/h. [Conditional Expression]

In a case in which the above Conditional Expression is satisfied, areas of the first and second exciting electrodes 152 and 154 facing each other on the vibration arms 120 and 121 may be increased, such that driving efficiency of the tuning fork vibrator 100 may be improved.

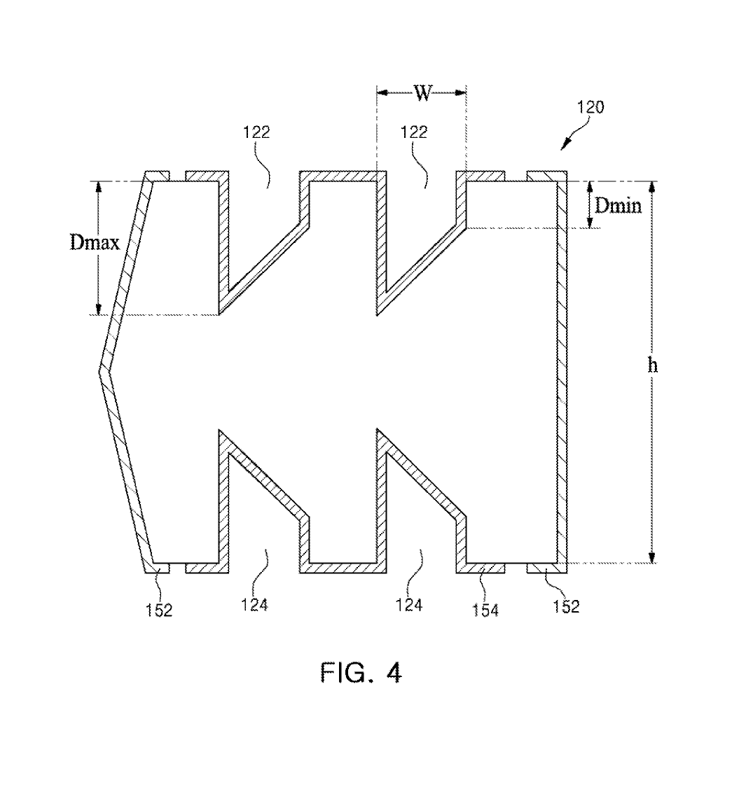

An example form of the grooves 122 and 124 of the tuning fork vibrator 100 will be described with reference to FIG. 4.

The depths of the grooves 122 and 124 may be varied in the vibration arms 120 and 121. For example, a depth of the grooves 122 and 124 may decrease from a first point toward a second point. As another example, the grooves 122 and 124 may have a cross-sectional shape in which three straight lines are connected to each other. Each surface may have a gradient of 45 degrees or less with respect to a vertical line in the first direction (the height direction of the vibration arms 120 and 121).

A depth of the grooves 122 and 124 may have a predetermined ratio with respect to a height h of each of the vibration arms 120 and 121. For example, a minimum depth Dmin of the grooves 122 and 124 may satisfy the following Conditional Expression:

0.17<Dmin/h. [Conditional Expression]

In a case in which the above Conditional Expression is satisfied, areas of the first and second exciting electrodes 152 and 154 facing each other on the vibration arms 120 and 121 may be increased, such that driving efficiency of the tuning fork vibrator 100 may be improved.

Depths Dmax and Dmin of the grooves 122 and 124 may have a predetermined ratio with respect to a width W of the grooves 122 and 124. For example, a maximum depth Dmax of the groove 122 may satisfy at least one of the following Conditional Expressions with respect to the width W of the grooves 122 and 124:

3.3<Dmax/W [Conditional Expression]

3.30<Dmax/W<3.75. [Conditional Expression]

As another example, a minimum depth Dmin of the grooves 122 and 124 may satisfy at least one of the following Conditional Expressions with respect to the width W of the grooves 122 and 124:

1.3<Dmin/W [Conditional Expression]

1.3<Dmin/W<2.0. [Conditional Expression]

The minimum depth Dmin of the groove 122 and 124 may have a predetermined ratio with respect to the maximum depth Dmax of the grooves 122 and 124. For example, the minimum depth Dmin of the grooves 122 and 124 may satisfy at least one of the following Conditional Expressions with respect to the maximum depth Dmax of the grooves 122 and 124:

0.3<Dmin/Dmax [Conditional Expression]

0.3<Dmin/Dmax<0.45. [Conditional Expression]

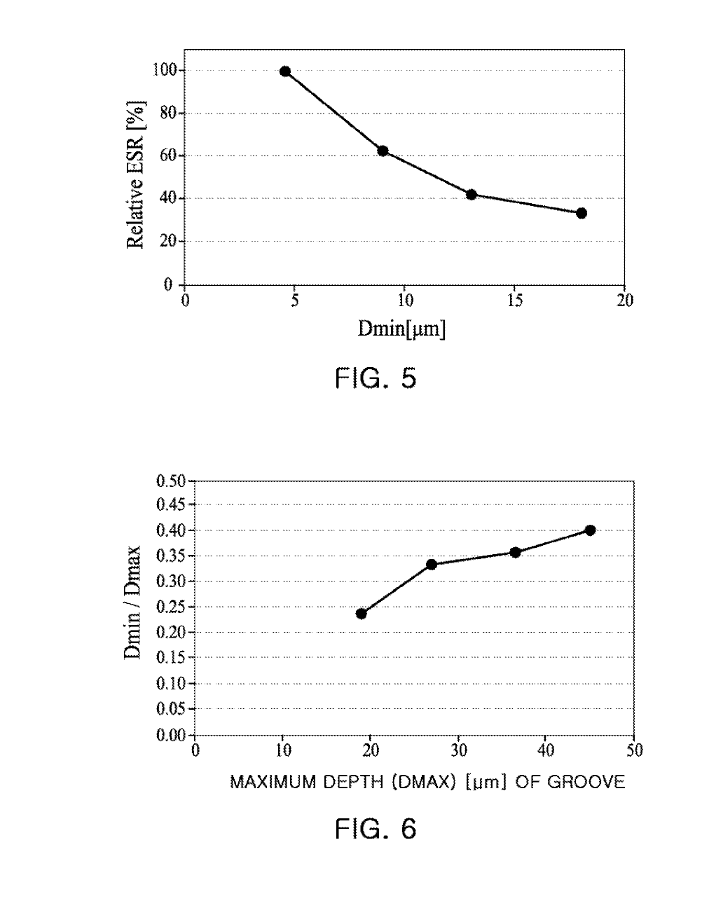

A relationship between a minimum depth Dmin of a grooves 122 and 124 and an equivalent series resistance (ESR) will be described with reference to FIG. 5.

The tuning fork vibrator 100, according to the example of FIG. 5, may be configured to have low ESR. For example, the minimum depth Dmin of the grooves 122 and 124 formed in the vibration arms 120 and 121 may be 15 μm or more.

The minimum depth Dmin of the grooves 122 and 124 described above may be advantageous in lowering ESR in vibration arms having the same form as confirmed from a graph of FIG. 5.

A relationship between a ratio (Dmin/Dmax) of a minimum depth of the grooves 122 and 124 to a maximum depth of the grooves 122 and 124 and an ESR will be described with reference to FIG. 6.

In the tuning fork vibrator 100 according to the example of FIG. 6, the minimum depth Dmin of the groove 122 or 124 may have a predetermined ratio with respect to the maximum depth Dmax of the grooves 122 and 124. For example, the minimum depth Dmin of the grooves 122 and 124 may satisfy the following Conditional Expression with respect to the maximum depth Dmax of the grooves 122 and 124. For reference, a horizontal axis in FIG. 6 is a maximum depth of the grooves 122 and 124.

0.3<Dmin/Dmax<0.45 [Conditional Expression]

The above Conditional Expression may be one condition for optimizing vibration efficiency of the vibration arms 120 and 121 formed of crystal. For example, in a case in which Dmin/Dmax is outside of a lower limit value of the above Conditional Expression, areas of the first and second exciting electrodes facing each other on the vibration arms are substantially small, such that vibration efficiency may be low. As another example, in a case in which Dmin/Dmax is outside of an upper limit value of the above Conditional Expression, it may be substantially difficult to manufacture the vibration arms, and it may not be easy to form the exciting electrodes on the grooves 122 and 124.

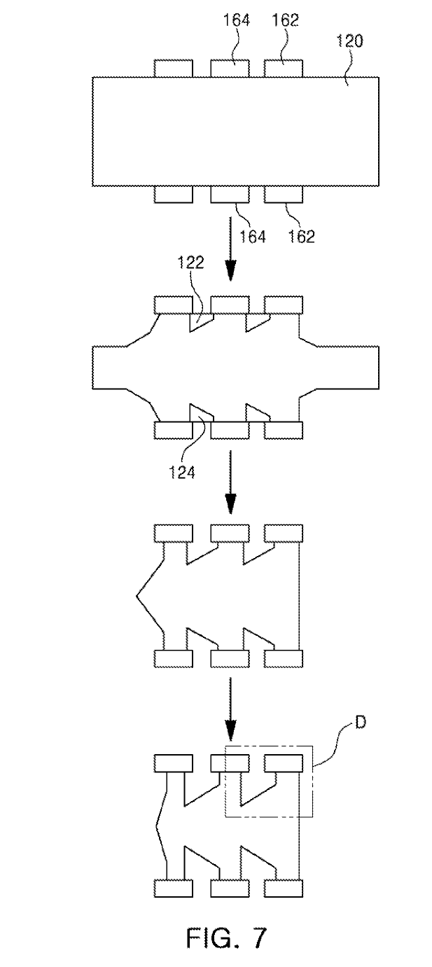

A process of forming the grooves 122 and 124 in the tuning fork vibrator 100 will be described with reference to FIG. 7.

The grooves 122 and 124 of the vibration arms 120 and 121 may be formed through the following operations.

1) Operation of Forming Mask Pattern (First Drawing of FIG. 7)

In a first operation, mask patterns 162 and 164 are formed on a member (for example, a crystal member) forming the vibration arm 120. For example, mask patterns 162 and 164 may be formed on first and second surfaces (upper and lower surfaces in FIG. 7) of the member forming the vibration arm 120.

The mask patterns 162 and 164 may be spaced apart by predetermined gaps. For example, the mask patterns 162 and 164 may be spaced apart by a gap that is narrower than a width of the grooves 122 and 124. Forms of the mask patterns 162 and 164 disposed as described above may be advantageous in deeply forming the grooves 122 and 124.

2) Etching Operation (Second to Fourth Drawings in FIG. 7)

In a subsequent operation, the members configuring the vibration arm 120 is etched to form the grooves 122 and 124 between adjacent mask patterns 162 and 164. For example, the members configuring the vibration arm 120 may be etched for several tens of hours or several hours by a wet etching scheme.

The vibration arm 120 formed of crystal may be etched to have directionality. For example, the grooves 122 and 124 of the vibration arm 120 may include both of deeply etched portions and shallowly etched portions, as seen in FIG. 7. Therefore, performance of the vibration arm 120 may depend on a minimum depth of the grooves 122.

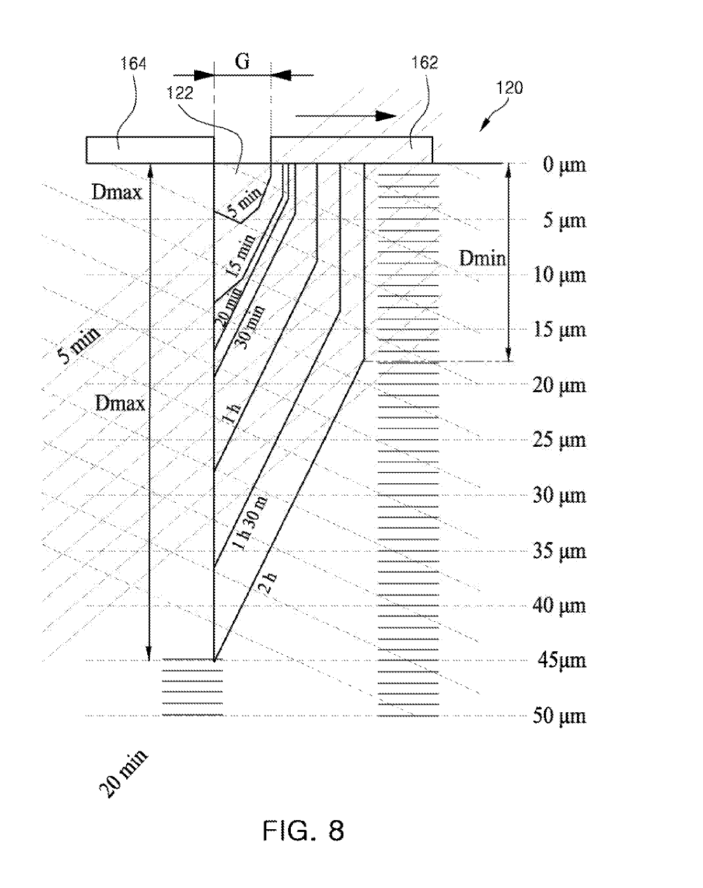

A relationship between a mask pattern and a size of a grooves 122 and 124 will be described with reference to FIG. 8.

As shown in FIG. 8, a gap G between first and second mask patterns 162 and 164 may be adjusted to optimize depths Dmax and Dmin of the grooves 122 and 124. For example, the depth of the grooves 122 and 124 formed in the vibration arm 120 may have a predetermined ratio with respect to the gap G between the mask patterns 162 and 164. For example, the minimum depth Dmin of the grooves 122 and 124 may satisfy one or more of the following Conditional Expressions with respect to the gap G between the mask patterns 162 and 164:

3.0<Dmin/G [Conditional Expression]

3.0<Dmin/G<6.0. [Conditional Expression]

As another example, the maximum depth Dmax of the grooves 122 and 124 may satisfy one or more of the following Conditional Expressions with respect to the gap G between the mask patterns 162 and 164:

4.0<Dmax/G [Conditional Expression]

8.0<Dmax/G<11.0. [Conditional Expression]

The above Conditional Expressions may be optimized conditions for forming the grooves 122 and 124 having a predetermined depth in the vibration arm 120. For example, in a case in which Dmin/G and Dmax/G are outside of lower limit values of the above Conditional Expressions, the mask patterns 162 and 164 may shorten an etching time required for forming the grooves 122 and 124, but may be disadvantageous in enlarging the minimum depth Dmin of the grooves 122 and 124.

The gap G between the first and second mask patterns 162 and 164 may satisfy the following Conditional Expression with respect to the height h of the vibration arm 120. For reference, in the example of FIG. 8, the gap G between the first and second mask patterns 162 and 164 may be 5.0 μm, and a height of the member configuring the vibration arm 120 may be 102 μm. In addition, the minimum depth Dmin of the grooves 122 and 124 may be 18 μm, and the maximum depth Dmax of the grooves 122 and 124 may be 45 μm.

G/h<0.05 [Conditional Expression]

Next, other forms of the tuning fork vibrator 100 will be described.

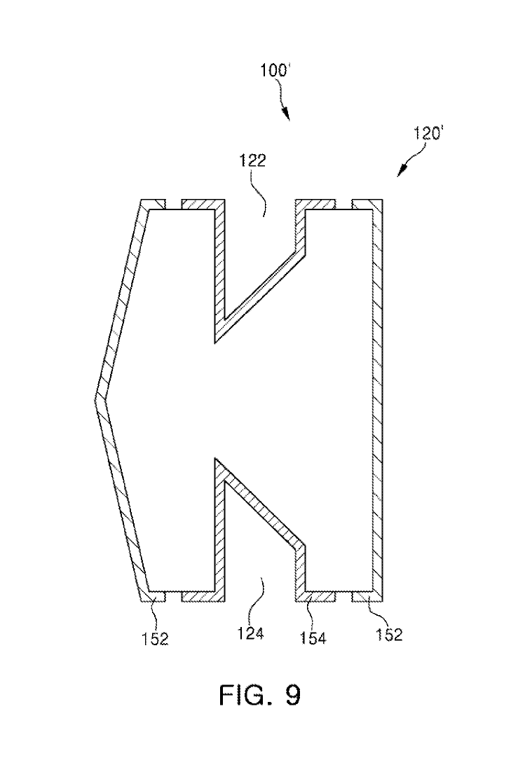

Another form of the tuning fork vibrator 100′ will be described with reference to FIG. 9.

The tuning fork vibrator 100′, according to an example, is similar to the tuning fork vibrator 100 described above, except that the tuning fork vibrator 100′ includes a vibration arm 120′ The vibration arm 120′ is similar to the previously described vibration arm 120, except that the number the grooves 122 and 124 formed in the first and second surfaces of the vibration arm 120′ is less than the number of grooves 122 and 124 formed in the first and second surfaces of the vibration arm 120. For example, there may be only one groove 122 formed in the first surface of the vibration arm 120′ and only one groove 124 formed in the second surface of the vibration arm 120′. The tuning fork vibrator 100′ having this form may be advantageous in being miniaturized.

As set forth above, according to examples disclosed herein, ESR characteristics of a tuning fork vibrator may be improved.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A tuning fork vibrator comprising:
a vibration arm comprising one or more grooves extending depthwise in a first direction; and
exciting electrodes configured to provide a level of driving force required for vibrations of the vibration arm,
wherein the one or more grooves have a cross-sectional shape in which a depth of the grooves decreases from a first point toward a second point, and
the depth of the one or more grooves at the second point is 30% or more of the depth of the grooves at the first point.

2. The tuning fork vibrator of claim 1, wherein the depth of the one or more grooves at the first point is 30% or more of a height of the vibration arm in the first direction.

3. The tuning fork vibrator of claim 1, wherein the one or more grooves have a cross-sectional shape including lines having an angle of inclination with respect to a vertical line in the first direction.

4. The tuning fork vibrator of claim 1, wherein the one or more grooves are formed, respectively, in first and second surfaces of the vibration arm that are perpendicular to the first direction.

5. The tuning fork vibrator of claim 1, wherein the one or more grooves are formed in first and second surfaces of the vibration arm that are perpendicular to the first direction to be symmetrical to each other.

6. The tuning fork vibrator of claim 1, wherein the one or more grooves are formed lengthwise in a second direction, which is a length direction of the vibration arm.

7. The tuning fork vibrator of claim 1, wherein the one or more grooves are formed at predetermined gaps in a third direction, which is a width direction of the vibration arm.

8. The tuning fork vibrator of claim 1, wherein the cross-sectional shape of the one or more grooves satisfies the following Conditional Expression:
0.3<Dmin/Dmax<0.45,
wherein Dmax is the depth of the one or more grooves at the first point and Dmin is the depth of the one or more grooves at the second point.

9. The tuning fork vibrator of claim 1, wherein the cross-sectional shape of the one or more grooves satisfies the following Conditional Expression:
Dmin/W<2.0,
wherein Dmin is the depth of the one or more grooves at the second point and W is a maximum width of the one or more grooves.

10. The tuning fork vibrator of claim 1, wherein the cross-sectional shape of the one or more grooves satisfies the following Conditional Expression:
0.16<Dmin/h<0.36,
wherein Dmin is the depth of the one or more grooves at the second point.

11. The tuning fork vibrator of claim 1, wherein the vibration arm is formed of crystal.

12. The tuning fork vibrator of claim 1, further comprising a mass member formed on the vibration arm.

13. A tuning fork vibrator comprising:
a vibration arm comprising one or more grooves extending depthwise in a first direction; and
mask patterns formed on the vibration arm at predetermined gaps between the mask patterns to form the one or more grooves,
wherein a minimum depth of the one or more grooves is greater than a gap between the mask patterns.

14. The tuning fork vibrator of claim 13, wherein the minimum depth (Dmin) of the one or more grooves satisfies the following Conditional Expression with respect to the gap (G) between the mask patterns:
3.0<Dmin/G.

15. The tuning fork vibrator of claim 13, wherein a maximum depth (Dmax) of the one or more grooves satisfies the following Conditional Expression with respect to the gap (G) between the mask patterns:
4.0<Dmax/G.

16. The tuning fork vibrator of claim 13, wherein the vibration arm is formed of a material having mechanical directionality.

17. A method of manufacturing a tuning fork vibrator, comprising:
forming mask patterns on at least one of an upper surface and a lower surface of a member forming a vibration arm; and
etching the member to form a groove extending between the mask patterns along a length of the member,
wherein the groove has a width in a direction corresponding to a direction of a gap between the mask patterns on the upper surface of the member or the lower surface of the member, and
wherein the gap between the mask patterns is narrower than the width of the groove.

18. The method of claim 17, wherein the groove has a cross-sectional shape in which the depth of the groove decreases from a first point toward a second point, and wherein the depth of the groove is perpendicular to the width of the groove.
